(19) United States
(12) Patent Application Publication
(10) Pub. No.: US 2001/0048139 A1
(43) Pub. Date: Dec. 6, 2001

(54) Deformation gauge

(76) Inventors: Robert Aigner, Munchen (DE); Christofer Hierold, Munchen (DE); Manfred Glehr, Wenzenbach (DE); Klaus-Gunter Oppermann, Holzkirchen (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 09/849,911

(22) Filed: May 4, 2001

Related U.S. Application Data
(63) Continuation of application No. PCT/DE99/03543, filed on Nov. 4, 1999.

(30) Foreign Application Priority Data
Nov. 4, 1998 (DE) 198 50 872.7

(51) Int. Cl. H01L 29/84

(52) U.S. Cl. 257/415

(57) ABSTRACT

A micromechanical sensor is described which contains electrodes that are disposed on a substrate, and electrode bars made of silicon that can move with regard to the electrodes. A deformation of the substrate is measured by determining differential changes in a capacity of the electrode bars in comparison to adjacently disposed electrodes. Two groups of electrode bars are preferably used which are interlocked with one another in an alternating comb-like manner, which, are separate from one another, and are interconnected at the ends thereof in an electrically conductive manner, and which are anchored on the substrate.

### CROSS-REFERENCE TO RELATED APPLICATION

This application is a continuation of copending International Application No. PCT/DE99/03543, filed Nov. 4, 1999, which designated the United States.

### BACKGROUND OF THE INVENTION

1. Field of the Invention

The present invention relates to a sensor being a semiconductor component that is suitable for measurement of material deformations, forces, torques, moments and distances.

Until now, strain gauges have been used for measuring small deformations in large-scale applications. The achievable accuracy when using such deformation gauges is about 0.5% of the total measurement range, and is thus considerably poorer than the measurement accuracy of other mechanical variables. The narrow temperature range within which strain gauges can be used, and the high power requirements for the resistance bridge that is connected are also problematic.

Semiconductor chips that have, for example, a semiconductor body composed of silicon can be deformed by the influence of pressures and tensile stresses. As a rule, operating characteristics become poorer in consequence. U.S. Pat. No. 5,337,606 describes an acceleration sensor which can be produced micro-mechanically and in which a structure in the form of a grating and composed of polysilicon is anchored such that it can move relative to the substrate. Any deflection of the grating structure is detected by a capacitive measurement by electrodes that are in the form of strips and are mounted on the substrate. Deformation of the substrate in such a component is at best suitable for making the measurement result poorer.

### SUMMARY OF THE INVENTION

It is accordingly an object of the invention to provide a deformation gauge that overcomes the above-mentioned disadvantages of the prior art devices of this general type, which can be used over a wider temperature range with low power consumption, and which allows high resolution and the production of digital output signals while having good resistance to overloading.

With the foregoing and other objects in view there is provided, in accordance with the invention, a semiconductor component functioning as a sensor. The semiconductor component has a substrate, first electrodes disposed on or in the substrate, and second electrodes disposed on or in the substrate. The first electrodes and the second electrodes are disposed alternately with regard to each other. Electrode bars are disposed parallel to one another and electrically insulated from the first and second electrodes and move relative to the substrate. The first and second electrodes run in a form of strips parallel to the electrode bars. The electrode bars in each case are mounted on the substrate such that the electrode bars are electrically conductively connected at one end to others of the electrode bars. The electrode bars are disposed relative to the first and second electrodes such that, in an event of shear and strain of the substrate in a predetermined plane, a capacitance between an electrode bar and a first electrode adjacent to it, and a further capacitance between the electrode bar and a second electrode adjacent to it vary in opposite senses to one another.

The semiconductor component according to the invention is a micro-mechanical sensor which is based on the knowledge that the undesirable corruption of the measurements resulting from deformation of the semiconductor chip in conventional micro-mechanical sensors can be utilized metrologically for detection of such deformations or of the pressures and stresses on which these deformations are based. For this purpose, the deformation gauge according to the invention has bars which can move relative to the electrodes disposed firmly on or in the substrate and which are composed of an electrically conductive material, preferably of silicon or polysilicon, which is conductively doped. Deformation of the substrate can be detected by determining the differential capacitance changes of the bars with respect to the substrate electrodes disposed adjacent to them. Two mutually separate groups of electrode bars which are interleaved with one another alternately like a comb are preferably used, which bars are electrically conductively connected to one another at their ends and are anchored on the substrate. Such a configuration allows the use of a capacitive measurement bridge between four connections for electronic evaluation of the capacitance change.

In accordance with an added feature of the invention, a running bar is disposed on the substrate. The electrode bars have ends that are each attached to the running bar in such a manner that attached ends of the electrode bars are also moved in the event of shear in the substrate.

In accordance with an additional feature of the invention, a layer is disposed on the substrate. The electrode bars have ends that are each attached to the layer in such a manner that attached ends of the electrode bars are also moved in the event of shear in the substrate.

In accordance with another feature of the invention, a running bar is anchored at points to the substrate. The electrode bars have ends that are each attached to the running bar in such a manner that, in an event of strain in the substrate, attached ends of the electrode bars are held at a constant distance from the points anchoring the running bar on the substrate.

In accordance with a further feature of the invention, a layer is anchored at points to the substrate. The electrode bars have ends each attached to the layer in such a manner that, in an event of strain in the substrate, attached ends of the electrode bars are held at a constant distance from the points anchoring the layer on the substrate.

In accordance with another added feature of the invention, the electrode bars include first electrode bars and second electrode bars each mounted on the substrate such that they are electrically conductively connected to one another at one end and the first electrode bars and the second electrode bars are interleaved with one another like a comb. The first electrodes, the second electrodes, the first electrode bars and the second electrode bars have separate electrical connections.

In accordance with a concomitant feature of the invention, a capacitive measurement bridge is formed by the first electrode bars and the second electrode bars being disposed alternately.

Other features which are considered as characteristic for the invention are set forth in the appended claims.

Although the invention is illustrated and described herein as embodied in a deformation gauge, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIGS. 1a and 1b are diagrammatic, plan views of exemplary embodiments of a deformation sensor according to the invention;

FIG. 2 is a cross-sectional view of the deformation sensor illustrated in FIG. 1;

FIG. 3 is a circuit diagram for a capacitive measurement bridge of the configuration shown in FIG. 1b.

### DESCRIPTION OF THE PREFERRED EMBODIMENTS

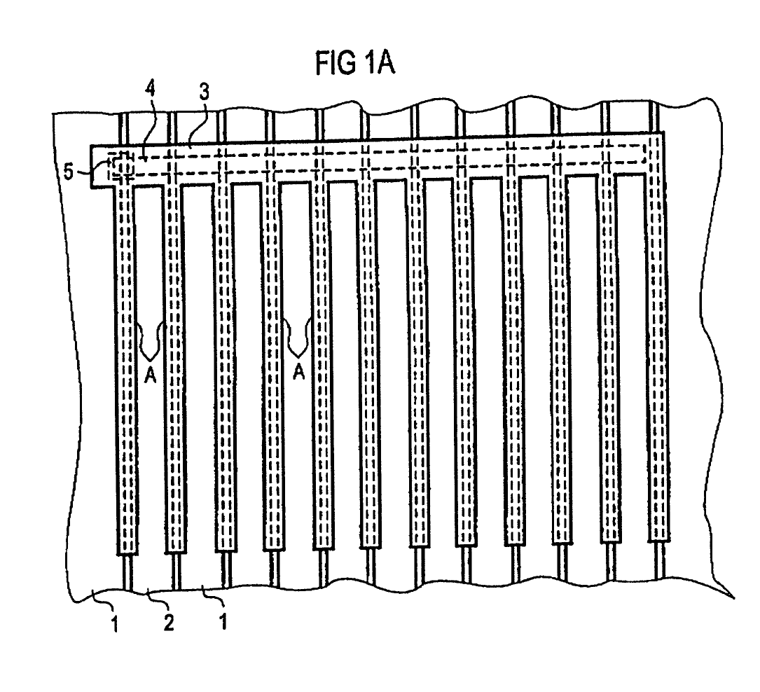

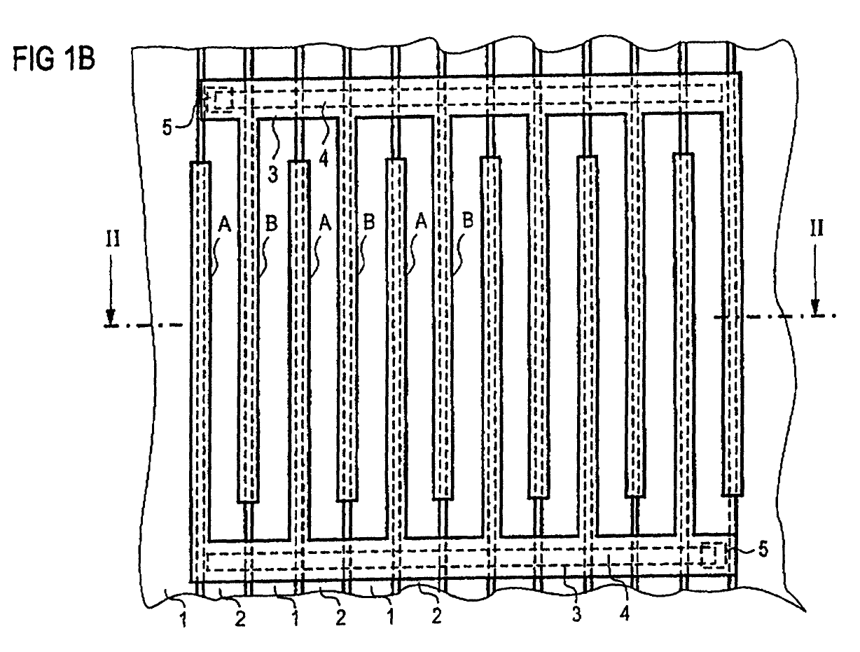

In all the figures of the drawing, sub-features and integral parts that correspond to one another bear the same reference symbol in each case. Referring now to the figures of the drawing in detail and first, particularly, to FIG. 1a thereof, there is shown a plan view of a deformation gauge formed as a semiconductor component, as can be produced by CMOS-compatible micro-mechanical techniques. An upper view of elements of existing electrodes, passivation or covers has been removed in the view in FIG. 1a. It is thus possible to see electrodes 1, 2 which are shown in FIG. 1a, in the form of strips, are disposed parallel to one another, and are formed in a substrate 6 (FIG. 2) or in layers applied to the substrate 6. The electrodes 1, 2 may, for example, be doped regions in the semiconductor material. Structures which can be produced micro-mechanically are applied to a top face of the semiconductor, which structures contain electrode bars A which are preferably electrically conductively connected to one another at one end by a transverse-running bar 3, and are mounted on the substrate 6. The mounting can be provided, for example, along the entire bar 3, for example in the region of an anchor 4 that is outlined by a dash line. Such anchoring is particularly suitable for measurement of shears in the substrate 6. One alternative is provided, for example, by mounting within the region of anchoring 5, likewise outlined by a dash line. Such anchoring, which allows the majority of the bar 3 to move with respect to the substrate 6, is particularly suitable for measurement of strains or compressions in the substrate 6. The electrode bars A shown in the drawing may all be attached to the same bar 3 at one end. The embodiment illustrated in FIG. 1b and having two separate bars 3, to which the electrode bars A, B are attached alternately, so that the electrode bars A, B are interleaved with one another like a comb, has metrological advantageous, which will be described further below.

FIG. 2 shows the cross section, as identified in FIG. 1b, of the described exemplary embodiments. FIG. 2 shows that an insulation layer 7 is applied to the substrate 6. The electrodes 1, 2, which are fit firmly relative to the substrate 6, are located on the insulation layer 7.

The electrodes 1, 2 can instead be formed entirely or partially by doped regions formed in the substrate 6, which are surrounded by a dielectric material or by a semiconductor material which is weakly doped or is doped in the opposite sense.

The electrode bars A, B are disposed, such that they can move with respect to the substrate 6, in the cavities that exist between the electrodes 1, 2. The structure is preferably covered over at the top by a passivation layer 8. The configuration illustrated here as an example has the advantage that the electrode bars A, B are surrounded by the electrodes 1, 2 such that a largely linear change in the capacitances or capacitance differences with respect to respectively adjacent electrodes occurs when the electrode bars A, B are deflected relative to the substrate 6.

The stresses that occur in a body are described by a second-stage tensor, which is referred to as the stress tensor. The tensor can be represented as a three-row square matrix, whose diagonal elements indicate the stress in each one of three mutually perpendicular directions, and whose other elements indicate the stresses in the respective planes at right angles to these directions, as shears. The stress tensor is symmetrical, owing to the elastic conditions in the body. A co-ordinate transformation can thus be used such that the stress tensor is a diagonal matrix in the new co-ordinate system. The axes that define the new co-ordinate system are the eigen vectors of the matrix, the main stress directions.

The diagonal elements are the associated eigen values, the main stresses. The shear stress and the shear distortion are at a maximum in the direction of the angle bisectors between the main stress directions.

The deformation gauge is intended to allow detection of deformation of the semiconductor body in the plane in which the electrodes 1, 2 are disposed, that is to say in the plane of the top face of the chip. Stresses and shears that occur in a plane are thus recorded. Thus, in the deformation gauge intended for shear measurement, the electrode bars A, B are preferably aligned along an angle bisector between the two main stress directions lying in the plane. The ends of the electrode fingers are preferably mounted on the substrate by the bar 3 in the surface (which is shown as an example in FIGS. 1a and 1b) of the anchor 4, which extends over the entire bar length. The stress state acting in the substrate 6 is not transmitted to the free-standing part of the electrode bars; the actual electrode bars remain free of deformation beyond the anchorage point, while the substrate 6 and the electrodes 1, 2 which are fit in it are deformed.

In the cross section which is shown in FIG. 2, it can be seen that, in this preferred embodiment, the electrodes 1 and 2 which are firmly attached to the substrate 6 preferably have flat extents above and below the electrode bars A, D. The flat elements are electrically conductively connected to one another, and are made mechanically robust, by supports 9. Owing to the at least partial overlap of the surfaces of the electrodes 1, 2 and of the electrode bars A, B, the capacitance change is essentially linear with respect to the deflection of the electrode bars A, B, and is thus approximately linear with respect to the shear deformation of the substrate 6. In this case, it is assumed that the electrode bars A, B move relative to the substrate 6 essentially in the plane in which they are disposed. Any vertical bending of the electrode bars A, B, or other manufacturing-dependent tolerances, are in this case largely insignificant. A distance between the electrode bars A, B and the vertical supports 9 of the fixed electrodes 1, 2 can be chosen to be sufficiently large that the conducive elements of the electrodes 1, 2 do not make any significant contribution to the capacitance change. A resistance of the micro-mechanical structure to overloading is provided by the large lateral distance between the electrode bars A, B and the supports 9.

In the described simple embodiment, in which all the electrode bars are attached to the same transverse-running bar 3 and are thus all electrically conductively connected to one another, the evaluation is carried out by recording the differential capacitance changes of the electrode bars A, B with respect to the respectively adjacent electrodes 1 and 2. The electrode bars A, B thus form the center connection of a capacitance half-bridge, which is formed by two variable capacitors connected in series. The external connections are formed by the electrodes 1 and 2. The value ΔC_{1A}=−ΔC_{2A}=n·ε₀·(d₁⁻¹+d₂⁻¹)·1²γ/2 is thus obtained as the capacitance change of the deformation gauge having n electrode bars of length 1, where γ is the value of the shear deformation, d₁ and d₂ are the values of the upper and lower air gap, respectively, between the electrodes 1, 2, and ε₀ the electrical field constant, also referred to as the absolute dielectric constant.

The electrode bar length 1 that can be achieved depends on technological characteristics. If there is a tensile stress or compressive stress in the silicon layer in which the electrode bars A, B are structured, the electrode bars are increasingly bent toward the free ends. It may thus be better to achieve high sensitivity levels of the deformation sensor with smaller air gaps between the electrodes, rather than with longer electrode bars.

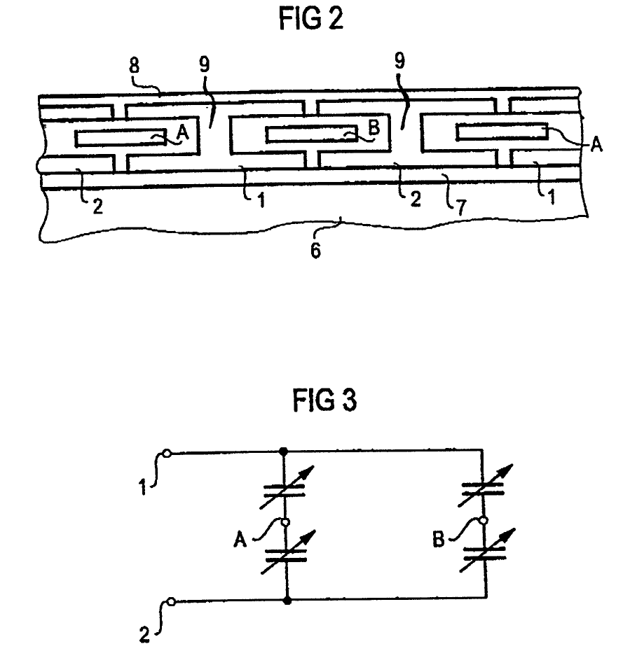

The preferred embodiment illustrated in FIG. 1b and having two groups of electrode bars A and B which are interleaved with one another like a comb has the advantage that a full capacitive bridge for detection of the measurement signals can be provided by using the four different connections. The associated circuit is illustrated schematically in FIG. 3. It can be seen from the circuit diagram that the electrode bars A and the electrode bars B each form variable capacitance capacitors with the adjacent electrodes 1 and 2 on different sides. Very minor mistuning of such capacitive bridges can be determined highly accurately by, for example, of Σ-Δ modulators using switched-capacitor-technology. In circuits such as this, which are known per se, differential SC input integrators are followed, for example, directly by a quantizer, whose output signal is fed back. The output signal from the modulator is a high-frequency bit stream, which can be further processed digitally by an electronic logic circuit that is preferably monolithically integrated on the same chip. The bit resolution which is achievable is governed by the ratio of the Σ-Δ operating frequency to the signal frequency. A decimation filter converts the high-frequency 1-bit signal to a low-frequency multi-bit signal, and at the same time provides low-pass filtering.

Owing to the symmetry of the electrode configuration shown in FIG. 1b, temperature fluctuations have little influence on the zero point of the measurement when the substrate 6 is not deformed. Thermal expansion can be assumed to be three-dimensionally isotropic, and thus does not produce any difference signals in the measurement bridge. The symmetry characteristics ensure very little lateral sensitivity to bending and warping of the chip. Tensile and compressive stresses along the electrode bars or the bar 3 use as the anchor, which result from production and are not caused by deformation of the substrate 6, do not lead to any difference signals in the measurement bridge. Any asymmetry which may result from adjustment errors during the manufacturing process can be compensated for by interconnecting two electrode configurations as shown in FIGS. 1a or 1b, which are disposed rotated through 90° with respect to one another. The sensor then contains two configurations as shown in FIGS. 1a and 1b. It is also possible to fit a number of such configurations on the same substrate 6, in order to improve the measurement accuracy further.

Effects from bending of the electrode bars and thermomechemical influences can be eliminated by suitable circuitry using a compensation capacitor. In the described preferred circuit embodiment, the compensation capacitor is connected in the feedback path of the SC input integrator and, in principle, has the same circuitry as that in FIG. 3, but in which the connections 1 and 2, and A and B, are connected to one another. Such a compensation capacitor can be formed by a further, identical micro-mechanical component.

In the alternative configuration, the deformation gauge whose anchor 5 on the substrate 6 has a small area is particularly suitable for strain measurement. Neither forces nor torques are introduced into the free-standing electrode structure, so that there is no deformation of the free-standing electrode bars when the substrate 6 is stretched or compressed. The measurement variable is the capacitance change of the electrode bars A, B with respect to the electrodes 1, 2 attached to the substrate 6. The value of the capacitance change when the substrate 6 deforms in this strain gauge is not proportional to the square of the length 1 of the electrode bars A, B, but is proportional to the product of the length 1 and the length of the bar 3.

The embodiment shown in FIG. 1b is preferable for the strain gauge, since the embodiment shown in FIG. 1a has comparatively high lateral sensitivity to shear distortion. In the configuration shown in FIG. 1b, the effects of shear distortion can be eliminated better. The electronic circuit that is connected can in principle correspond to the exemplary embodiment, as a shear sensor.

If one assumes thermal expansion to be three-dimensionally isotropic, then unequal thermal coefficients of expansion in the measurement object and in the substrate 6 of the deformation sensor connected to it, together with the electrode bars A, B, lead to small difference signals in the measurement bridge, which do not occur when measuring shear. These errors in the measurement of absolute strains cannot be suppressed by the compensation capacitor. Calibration by a measurement of the temperature of the sensor, if required, overcomes this in the same way as that used conventionally with strain gauges.

The active sensor area should be placed as close as possible to the center of the chip since this is where the stress state of the measurement object is best coupled into the chip and any edge effects which occur have decayed. This results in the chip size having minimum dimensions, which can be determined from the thickness of the chip and the mechanical characteristics of the mounting material, without any further difficulties. The mounting of the deformation gauge on the measurement object is subject to stringent requirements for the mechanical characteristics of the joint. However, in this respect, the deformation gauge does not differ from conventional strain gauges, so that the procedures known from strain gauges can be transferred as appropriate to the mounting of the deformation gauge according to the invention. Since the chip itself is resistant to overloading up to the ultimate stress limit of the material of the semiconductor body, the maximum deformation is defined by plastic effects or by destruction of the connecting layer to the measurement object.

Strain gauges are generally bonded. However, owing to the greater thermal load capacity of the deformation gauge according to the invention, other connection techniques are also feasible, such as soldering, anode bonding or glass bonding. Grinding the chip down to a thickness of 100 μm to 300 μm considerably reduces the shear load in the bonding joint. Further improvements are achieved with a chip that becomes thinner towards the edge.

The deformation gauge has the further advantage that a configuration of a number of the electrode configurations as shown in FIGS. 1a or 1b on the same chip is feasible, even with different alignments relative to the substrate 6, and thus different sensitivity axes.

We claim:

1. A semiconductor component functioning as a sensor, comprising:
a substrate;
first electrodes disposed one of on and in said substrate;
second electrodes disposed one of on and in said substrate, said first electrodes and said second electrodes disposed alternately with regard to each other; and
electrode bars disposed parallel to one another and electrically insulated from said first and second electrodes and move relative to said substrate, said first and second electrodes run in a form of strips parallel to said electrode bars, said electrode bars in each case mounted on said substrate such that said electrode bars are electrically conductively connected at one end to others of said electrode bars, said electrode bars disposed relative to said first and second electrodes such that, in an event of shear and strain of said substrate in a predetermined plane, a capacitance between an electrode bar and a first electrode adjacent to it, and a further capacitance between said electrode bar and a second electrode adjacent to it vary in opposite senses to one another.

2. The semiconductor component according to claim 1, including a running bar disposed on said substrate, said electrode bars have ends that are each attached to said running bar in such a manner that attached ends of said electrode bars are also moved in the event of shear in said substrate.

3. The semiconductor component according to claim 1, including a layer disposed on said substrate, said electrode bars have ends that are each attached to said layer in such a manner that attached ends of said electrode bars are also moved in the event of shear in said substrate.

4. The semiconductor component according to claim 1, including a running bar anchored at points to said substrate, said electrode bars having ends each attached to said running bar in such a manner that, in the event of strain in said substrate, attached ends of said electrode bars are held at a constant distance from said points anchoring said running bar on said substrate.

5. The semiconductor component according to claim 1, including a layer anchored at points to said substrate, said electrode bars having ends each attached to said layer in such a manner that, in the event of strain in said substrate, attached ends of said electrode bars are held at a constant distance from said points anchoring said layer on said substrate.

6. The semiconductor component according to claim 1, wherein said electrode bars include first electrode bars and second electrode bars each mounted on said substrate such that they are electrically conductively connected to one another at one end, said first electrode bars and said second electrode bars are interleaved with one another like a comb, and said first electrodes, said second electrodes, said first electrode bars and said second electrode bars have separate electrical connections.

7. The semiconductor component according to claim 6, wherein a capacitive measurement bridge is formed by said first electrode bars and said second electrode bars being disposed alternately.
